(19) United States
(12) Patent Application Publication
(10) Pub. No.: US 2026/0010498 A1
(43) Pub. Date: Jan. 8, 2026

(54) SCALABLE I/O CONTROLLER FOR DISTRIBUTED VEHICLE CONTROL SYSTEM

(71) Applicant: MAGNA CLOSURES INC., Newmarket (CA)

(72) Inventors: Peter Sercl, Newmarket (CA); Kasper Pilested, Newmarket (CA); Ramesh Sethuraj, Newmarket (CA); Meetkumar Patel, Newmarket (CA)

(21) Appl. No.: 19/261,411

(22) Filed: Jul. 7, 2025

Related U.S. Application Data
(60) Provisional application No. 63/668,677, filed on Jul. 8, 2024.

(51) Int. Cl. G06F 13/20; B60R 16/023; H05K 7/14

(52) U.S. Cl. CPC G06F 13/20; B60R 16/0231; H05K 7/1427; G06F 2213/40

(57) ABSTRACT

An electrical control system for a vehicle includes: a plurality of zone controllers each associated with a corresponding physical region of the vehicle, and each having an identical hardware configuration; a high-speed digital communications network interconnecting the plurality of zone controllers; and a plurality of I/O controllers, or sub-zonal or edge controllers, each including a processor and at least one of: an input circuit configured to receive a digital or analog signal from a sensor device, or an output circuit configured to produce and transmit a digital or analog signal to an output device. The plurality of I/O controllers each have a commonized configuration, including an identical enclosure and an identical main circuit board. Different I/O controllers of the plurality of I/O controllers have at least one of: processors having different performance characteristics, or the input circuit or the output circuit having different arrangements of hardware components.

### CROSS-REFERENCE TO RELATED APPLICATION

This U.S. utility patent application claims the benefit of U.S. Provisional Patent Application No. 63/668,677, filed Jul. 8, 2024, the contents of which is incorporated herein by reference in its entirety.

### FIELD

The present disclosure relates generally to electrical and electronic control systems for vehicles, such as passenger cars or trucks.

### BACKGROUND

Electrical and Electronic (E/E) architectures for control in automotive vehicles, such as passenger cars and trucks, are increasingly complex with the introduction of additional features in each of several different domains, such as advanced driver assistance systems (ADAS), Body, Powertrain, Chassis, Exteriors, etc.

Many conventional electronic control units (ECUs) for onboard systems in vehicles include the following components: complex, low voltage, low current computing components, such as processors, controllers, System-on-Chip (SoC), etc.; and high voltage, high current power electronic devices, such as amplifier and driver components (H-bridges, MOSFETs, relays, etc.).

Traditional approaches to designing a vehicle's E/E architecture may be increasingly expensive and may impose limits on desirable functionality, such as over-the-air (OTA) updates. The automotive industry has responded to the consumer trends by gradually adding more and more electronic control units (ECUs). Operating those ECUs includes millions of lines of code and hundreds of specialized suppliers and parts. Many traditional E/E architectures have reached their scalability limits. Such traditional E/E architectures can only be surpassed by a technological shift, which in turn creates new challenges.

I/O controllers (a.k.a. edge controllers or sub-zonal controllers) may be distributed near sensors and actuators to be controlled. There are advantages in having different I/O controllers that are tailored to specific requirements, such as a particular number and type of output channels for a given location or zone. However, these different I/O controllers may have increased cost and supply chain issues. Alternatively, a common I/O controller base design may be used for many different I/O controllers in a vehicle. However, this option also has disadvantages in increased costs, and because unused hardware components and processor capacity may be underleveraged.

### SUMMARY

The present disclosure provides an electrical control system for a vehicle. The electrical control system includes: a plurality of zone controllers each associated with a corresponding physical region of the vehicle, and each having an identical hardware configuration; a high-speed digital communications network interconnecting the plurality of zone controllers; and a plurality of I/O controllers. Each of the I/O controllers includes a processor and at least one of: an input circuit configured to receive a digital or analog signal from a sensor device, or an output circuit configured to produce and transmit a digital or analog signal to an output device. The plurality of I/O controllers each have a commonized configuration, including an identical enclosure and an identical main circuit board. Different I/O controllers of the plurality of I/O controllers have at least one of: processors having different performance characteristics, or at least one of the input circuit or the output circuit having different arrangements of hardware components.

The present disclosure also provides a domain control system for a vehicle. The domain control system includes: a modular electronic control unit; and a plurality of I/O controllers located remotely from the modular electronic control unit and in functional communication therewith via a controller network interconnection. The modular electronic control unit includes a central compute board, optionally disposed within a central enclosure, and including one or more high-performance processor devices configured to perform one or more application software functions. The plurality of I/O controllers each include a processor and at least one of: an input circuit configured to receive a digital or analog signal from a sensor device, or an output circuit configured to produce and transmit a digital or analog signal to an output device. The plurality of I/O controllers each have a commonized configuration, including an identical enclosure and an identical main circuit board. Different I/O controllers of the plurality of I/O controllers have at least one of: processors having different performance characteristics, or at least one of the input circuit or the output circuit having different arrangements of hardware components.

The present disclosure also provides an I/O controller for a control system in a vehicle. The I/O controller includes: a main circuit board; an enclosure containing the main circuit board; and at least one of: an input circuit configured to receive a digital or analog signal from a sensor device, or an output circuit configured to produce and transmit a digital or analog signal to an output device. The main circuit board is configured to physically and electrically receive one of a plurality of different processors each having different performance characteristics. The I/O controller is configured for functional communication with a remote electronic control unit via a controller network interconnection.

The present disclosure also provides an I/O controller for a control system in a vehicle. The I/O controller includes a main circuit board, and an enclosure containing the main circuit board. The main circuit board includes a plurality of footprints each configured to receive one or more hardware components to define one of: an input circuit configured to receive a digital or analog signal from a sensor device, or an output circuit configured to produce and transmit a digital or analog signal to an output device. The I/O controller is operable with at least one of the footprints populated with hardware components, and wherein the at least one of the footprints populated with hardware components is fewer than all of the footprints, thereby providing the I/O controller with a given number of I/O channels that is fewer than a number of I/O channels corresponding to all of the footprints being populated. The I/O controller is configured for functional communication with a remote electronic control unit via a controller network interconnection.

The present disclosure provides an implementation of a common hardware platform or family solution, which is scalable and modular to facilitate up/down contenting within the same physical envelope to address varying customer needs. This may be done through non-population of components, modular connectors, standardized housing designs, or any combination of the above hardware variations while sharing common software throughout all variants. This software may follow a standard such as the automotive open system architecture (AUTOSAR) framework so that code would be portable across devices within the product family.

The present disclosure also provides an electrical control system for a vehicle, including a plurality of zone controllers each associated with a corresponding physical region of the vehicle, wherein each zone controller is configured to control at least one device located within the corresponding physical region of the vehicle, where each zone controller comprises a configuration that is common among the plurality of zone controllers and a configuration that is specialized for controlling the at least one device of the corresponding physical region of the vehicle.

These and other aspects of the present disclosure are disclosed in the following detailed description of the embodiments, the appended claims, and the accompanying figures.

### BRIEF DESCRIPTION OF THE DRAWINGS

Further details, features and advantages of designs of the invention result from the following description of embodiment examples in reference to the associated drawings.

FIG. 1 shows a top view of a vehicle with a schematic diagram showing various electrical devices, controllers, and wiring interconnections, and with four zones.

FIG. 2 shows a block diagram of a network topology in a vehicle;

FIG. 3 shows a block diagram showing Zone electrical control units (ECUs) in a Zonal Architecture in accordance with an aspect of the present disclosure;

FIG. 4 shows a top view of a vehicle with a schematic diagram showing devices and interconnections therebetween in Zonal Architecture in accordance with an aspect of the present disclosure;

FIG. 5 shows a schematic diagram of a second vehicle including a domain control system with a body ECU having an integrated power control circuit board, and with additional power control circuit boards located remotely from the body ECU;

FIG. 6A shows a schematic diagram of a third vehicle with a distributed electrical control system, in accordance with the present disclosure;

FIG. 6B shows a schematic diagram possible hardware platforms utilized with the with the distributed electrical control system of the present disclosure;

FIG. 7A shows an I/O controller for a distributed electrical control system of a vehicle, in accordance with the present disclosure;

FIG. 7B shows an I/O controller for a distributed electrical control system of a vehicle, in accordance with the present disclosure;

FIG. 8 shows a schematic diagram of an I/O controller for a distributed electrical control system of a vehicle, and with a low-end configuration, in accordance with the present disclosure;

FIG. 9 shows a schematic diagram of an I/O controller for a distributed electrical control system of a vehicle, and with a mid-end configuration, in accordance with the present disclosure;

FIG. 10 shows a schematic diagram of an I/O controller for a distributed electrical control system of a vehicle, and with a high-end configuration, in accordance with the present disclosure; and

FIG. 11 shows reusable software modules portable across different microcontrollers and hardware platforms in accordance with aspects of the present disclosure.

### DETAILED DESCRIPTION

Referring to the drawings, the present invention will be described in detail in view of following embodiments.

It is an objective of the systems and methods of the present disclosure to provide an Electrical and Electronic (E/E) architecture that is cost efficient, reduces harness complexity, consolidates [feature application] software. It is also an objective of the systems and methods of the present disclosure to simplify and unify the software development process for an E/E architecture in a vehicle. It is also an objective of the systems and methods of the present disclosure to support over-the-air (OTA) updates.

The systems and methods of the present disclosure provide a single-zone ECU hardware design, which can provide improvements in lifecycle management (LCM), manufacturing, cost, maintenance, etc. The systems and methods of the present disclosure provide for a cost-efficient zone controller design, due to distributed/shared performance requirements of the multiple zone controllers. Each zone controller may only need to be able to partially execute a feature, since the functions in the feature can be hosted on multiple controllers. For example, processing signals from multiple different radar sensors can be performed by each of several different zone controllers, and those signals may be combined at a higher level, such as by fusing object data obtained from the different zone controllers.

The single-zone ECU hardware design of the present disclosure may enable use of a single, combined, software development environment, which may provide improvements in software development cost, tools, LCM, OTA, cybersecurity, etc.

The systems and methods of the present disclosure provide an optimization method for ECU location and SW hosting allocation, which can enable optimizing system performance vs. cost. The systems and methods of the present disclosure provide an optimization method and runtime scheduler for load balancing of the multiple zone controllers in the system. The system architecture of the present disclosure allows for adding or modifying SW features across the vehicle and for a variety of different applications including, but not limited to, infotainment.

According to an aspect of the present disclosure, an E/E system for a vehicle includes a high-speed Ethernet backbone. Such high-speed Ethernet may operate at speeds of 10 Gigabit per second (Gbps) or greater. This Ethernet backbone may replace CANbus architectures used in traditional E/E systems. Branching off this Ethernet backbone may be one or more CAN-FD, CAN-XL, or lower bandwidth Ethernet networks tying together the I/O controller devices within different sub-zones within the four primary vehicle zones.

According to another aspect of the present disclosure, an E/E system for a vehicle provides for hardware consolidation, including consolidating multiple functions that are traditionally served by separate ECUs into new, multi-functional ECUs. According to another aspect of the present disclosure, an E/E system for a vehicle provides for Wiring Optimization. The E/E systems of the present disclosure provide consolidation of ECUs together with new topologies for the vehicle networks to reduce the needed cabling length, weight, and cost to a fraction of conventional system designs.

According to another aspect of the present disclosure, an E/E system for a vehicle provides a Software-Driven Service-Oriented Architecture. The vehicle software architecture is evolving towards a Service-Oriented Architecture that can accommodate the needed flexibility, security and agility for the new software-defined vehicles.

A unique aspect of the system of the present disclosure, is the re-use of one single Zone Controller design. For example, the system may include 4 zone controllers, each having an identical hardware configuration. The zone controllers may only differentiate in the software that is running on them. In some embodiments, none of the zone controllers in the system of the present disclosure may considered a “Gateway” or a “High Performance Compute (HPC)”.

In some embodiments, application software, such as software providing various features and functions, runs on the zone controllers. In some embodiments, the Zone Controllers only support communication interfaces. For example, the zone controllers may have no I/O connections. The zone controllers may have no field-accessible input connections to provide electrical interfaces for input devices, such as switches or sensors. The zone controllers may have no field-accessible output connections to provide electrical interfaces for output devices, such as indicators, speakers, or actuators.

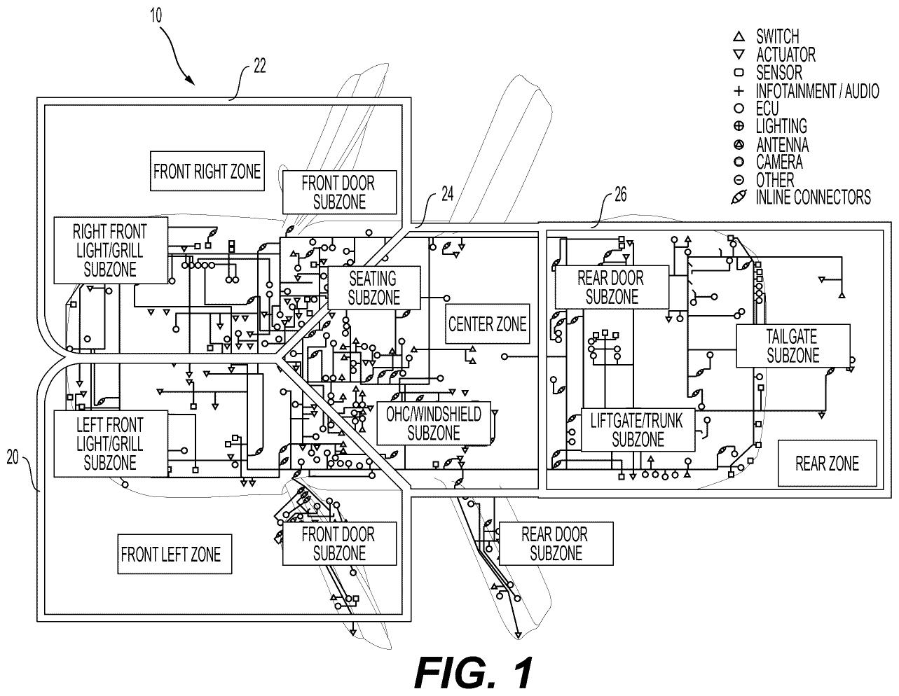

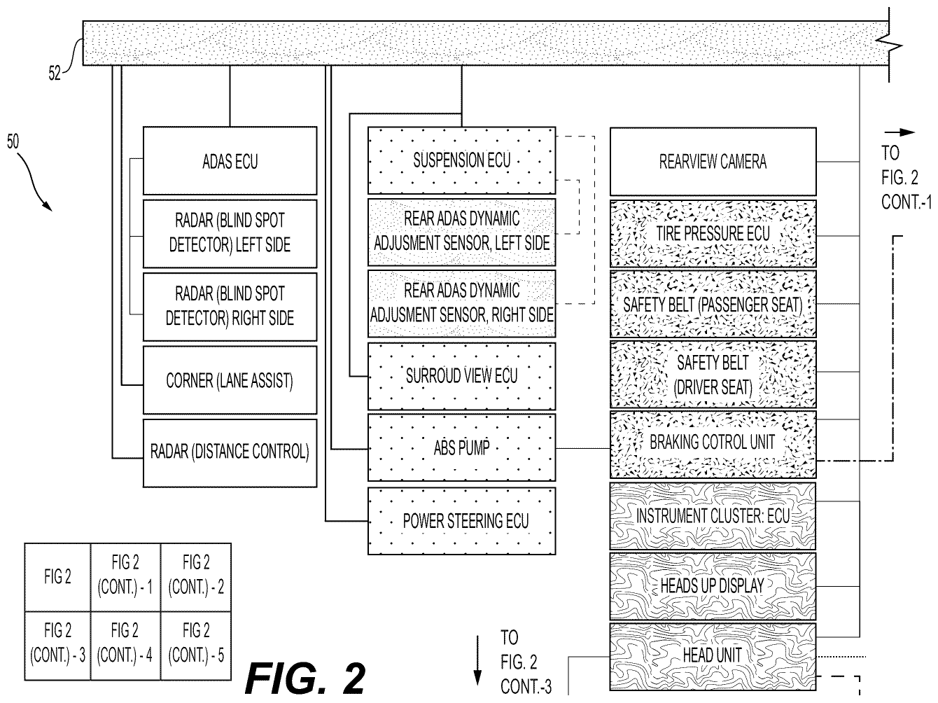

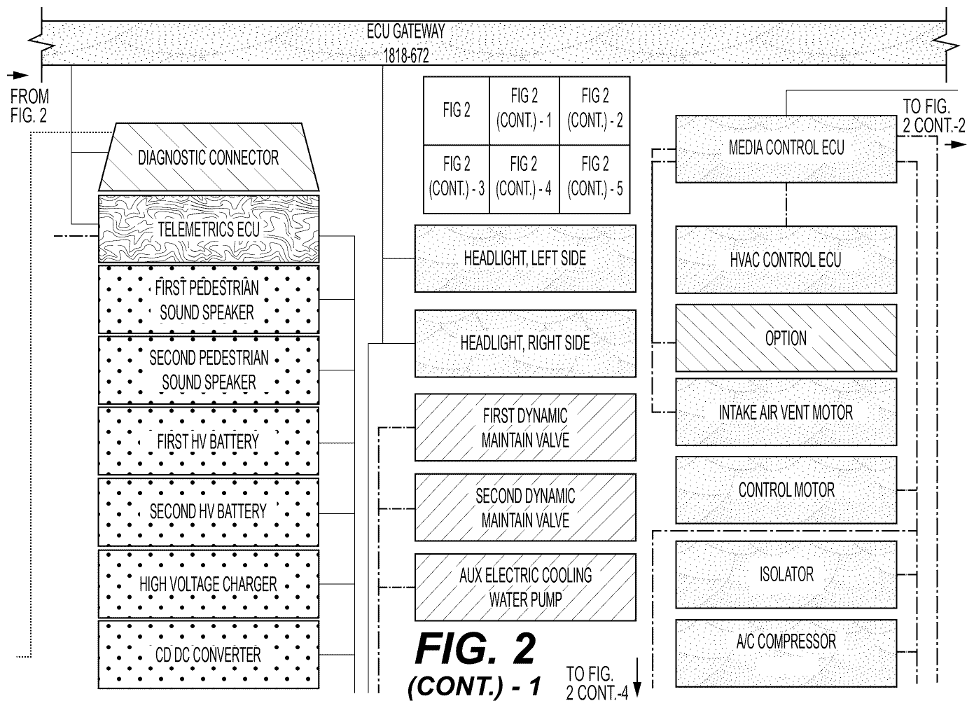

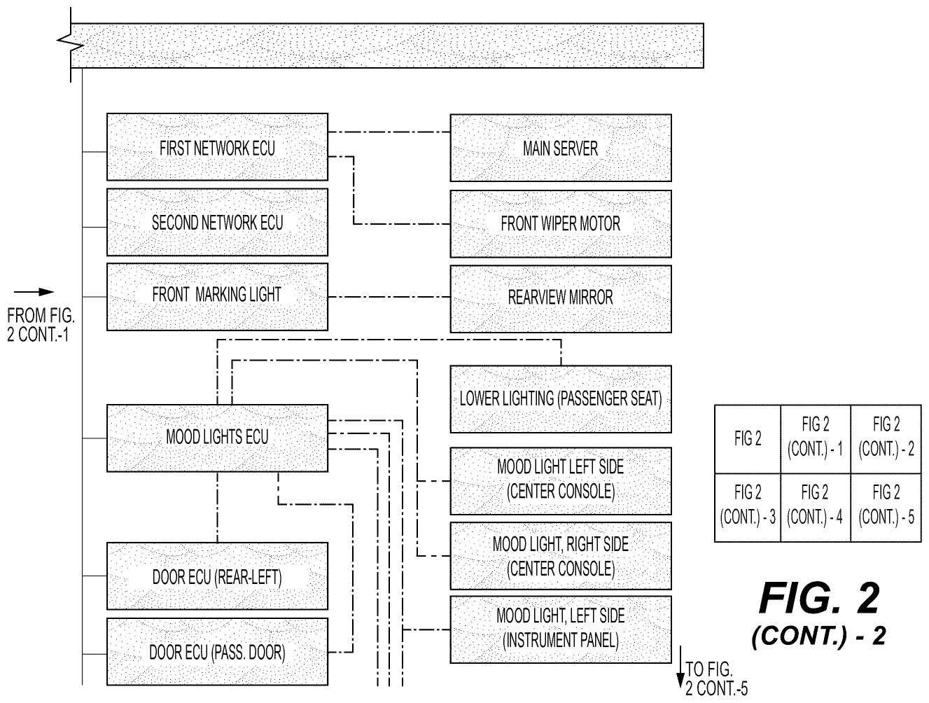

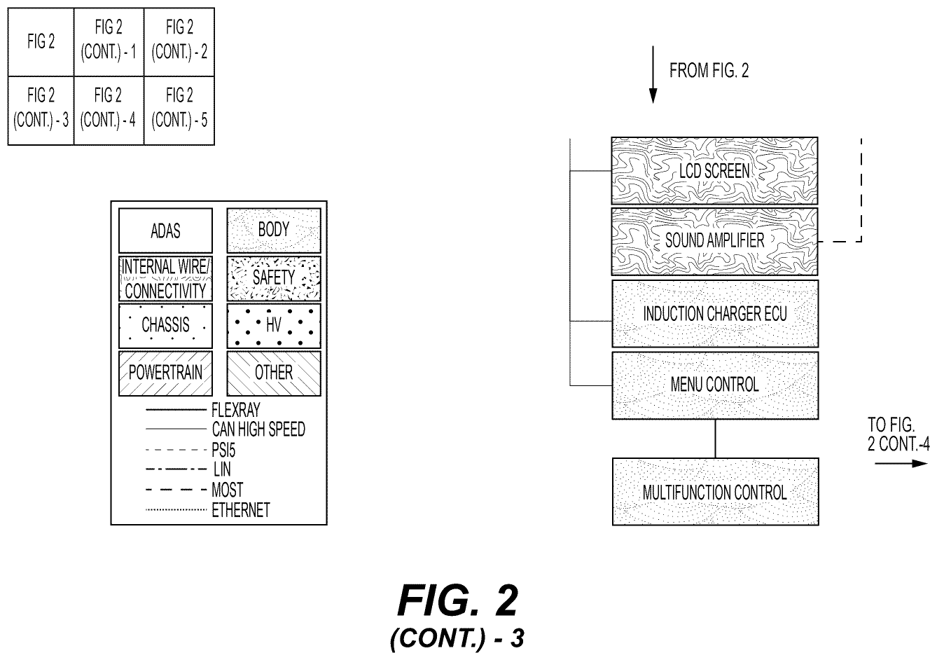

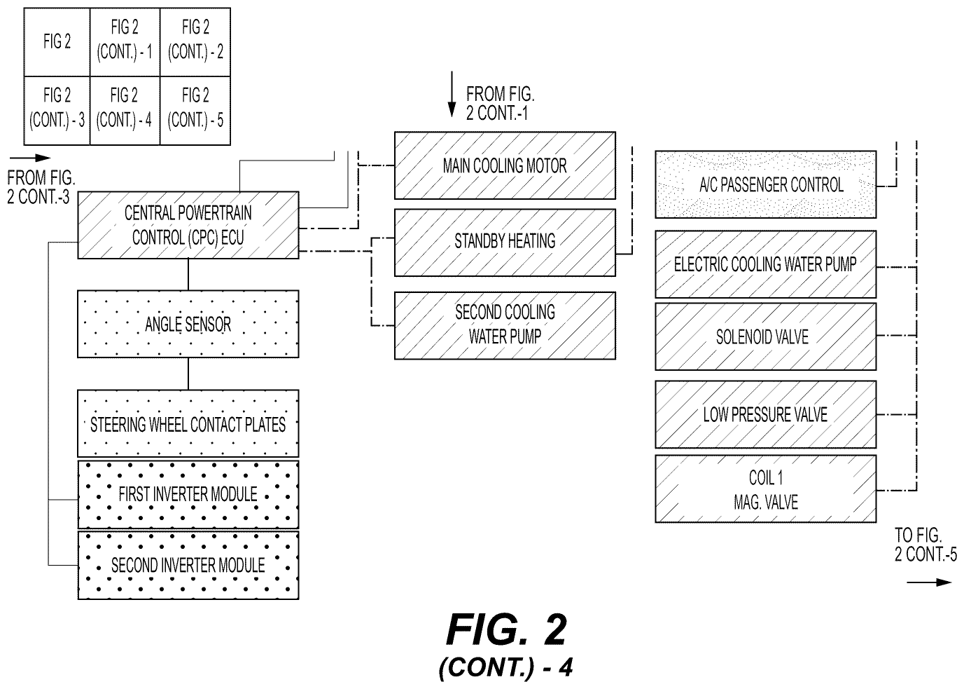

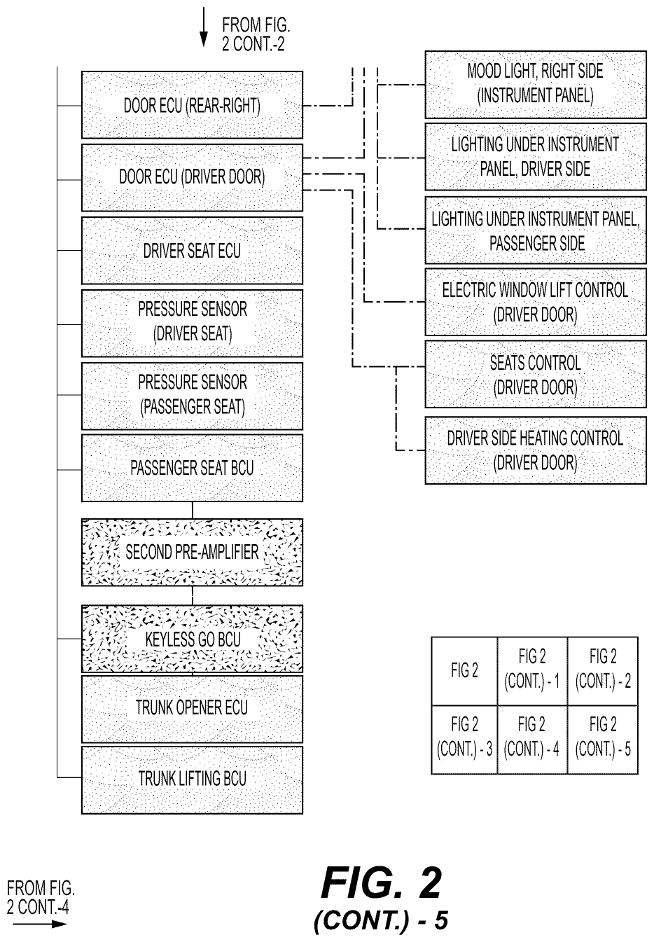

FIG. 1 shows a top view of a first vehicle 10 with a schematic diagram showing various electrical devices, electrical control units (ECUs), and wiring interconnections, and with the first vehicle 10 divided into four zones 20, 22, 24, 26. Front left zone 22 may include a front door subzone, a left front light/grille subzone and a frunk/hood subzone. Front right zone 22 may include a front door subzone and a right front light/grille subzone. Center zone 24 may include a rear door subzone, a seating subzone, and an overhead console subzone. Rear zone 26 may include a frunk/liftgate subzone and a taillight subzone. FIG. 1 shows an average vehicle. High-end vehicles may have up to 150 ECUs distributed across the first vehicle 10. FIG. 2 shows a block diagram of a network topology 50 in the first vehicle 10. The network topology diagram of FIG. 2 lists the ECUs in the first vehicle 10 by communication bus. This diagram illustrates the distributed nature of all the software functions and applications. The network topology 50 includes an ECU gateway 52 that interconnects each of several different networks and functional groups of ECUs. The network topology diagram of FIG. 2 includes several different functional groups of ECUs, each identified with a different color, and including ADAS, Body, Instrumentation, Safety, Chassis, Audiovisual (AV), Powertrain (PT), and Other. The network topology diagram of FIG. 2 includes several different types of communications networks interconnecting the ECUs, each identified with a different color, and including FlexRay, high-speed CAN, PSI5, LIN, MOST, and Ethernet. However, the first vehicle 10 may include other categories of ECUs and/or different types of communications networks.

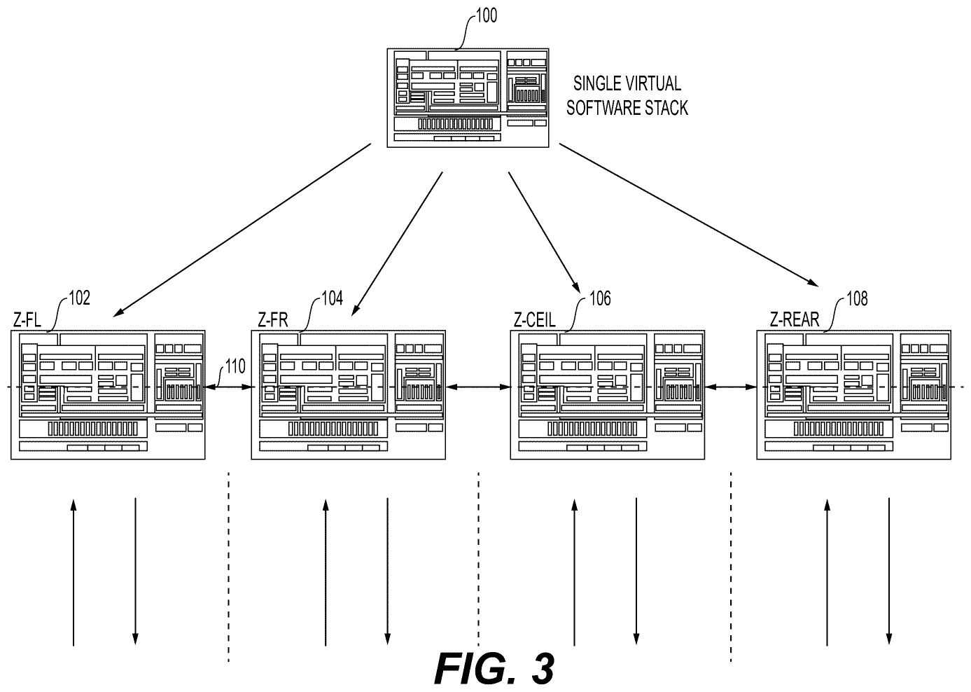

FIG. 3 shows a block diagram showing zone electrical control units (ECUs), also called zone controllers 102, 104, 106, 108, in a zonal architecture in accordance with an aspect of the present disclosure. The proposed zonal architecture consists of [for example] 4 identical zone controllers 102, 104, 106, 108 installed in different locations in the first vehicle 10. Each of the zone controller 102, 104, 106, 108 communicates with a unique collection of peripherals, as configured by software. At the application level, the zone architecture with the multiple zone controllers 102, 104, 106, 108 is perceived by the feature functions as a single software stack 100, where all signals are available, independent from the physical location to the hardware.

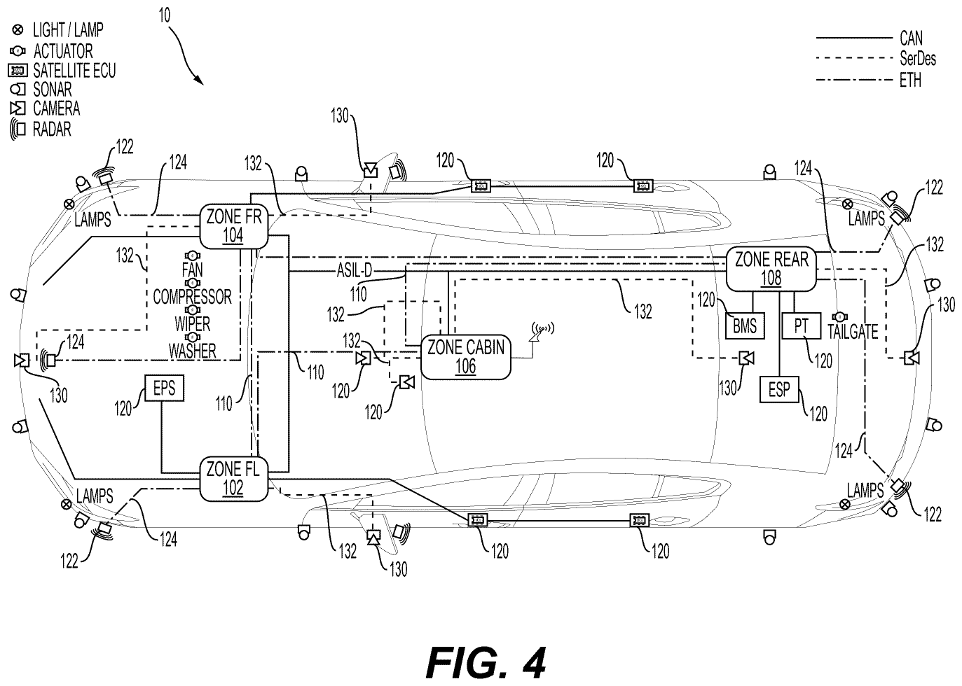

FIG. 4 shows a top view of the first vehicle 10 with a schematic diagram showing devices and interconnections therebetween in zonal architecture in accordance with an aspect of the present disclosure. FIG. 4 illustrates the zonal E/E architecture of the present disclosure, with four of the zone controllers 102, 104, 106, 108 connected via an Ethernet backbone in ring configuration. However, the zonal architecture of the present disclosure may be configured with any number of the zone controllers 102, 104, 106, 108, such as 3 or 5 of the zone controllers 102, 104, 106, 108, each having an identical hardware configuration.

The system of FIG. 4 may include one or more I/O controllers 120, which may also be called amplifier boards or EDGE ECUs, to provide electrical inputs and outputs, such as receiving discrete sensor inputs, and/or driving discrete actuators. In some embodiments, the system includes a plurality of I/O controllers, each including one or more input circuits and/or output circuits. The input circuits of the I/O controllers may each be configured to receive a digital or analog signal from a sensor device. The output circuits of the I/O controllers may each be configured to produce and transmit a digital or analog signal to an output device, such as an indicator, a speaker, or an actuator. In some embodiments, the output circuits of the I/O controllers may provide electrical power to operate the output device. Alternatively or additionally, an output device may receive power, such as electrical, hydraulic, pneumatic, or mechanical power, from another source. An output circuit of the I/O controller may provide a low-power control signal, which may control operation of a device using such an external power source. An actuator may include one or more electromechanical devices, such as solenoid actuators, electric motors, etc.

One or more of the I/O controllers 120 may be located at or near a location sensors and/or actuators connected thereto. For example, a door of the vehicle may include one of the I/O controllers 120 for monitoring various switches on the door and for controlling actuators for a latch and for a power window of the door.

As shown in FIG. 4, the I/O controllers 120 may include a powertrain controller (PT) configured to control and monitor functions of a powertrain, such as an engine, transmission, electric motor, motor drive, etc., an electronic stability control program controller (ESP) configured to control application of brakes and/or throttle, a battery management system controller (BMS) configured to monitor and control the charging and discharging of rechargeable batteries.

In some embodiments, one or more of the of the I/O controllers 120 may be located near or adjacent to a corresponding one of the zone controllers 102, 104, 106, 108 in order to interface with sensors and actuators in the vicinity of the zone controller. Each of the zone controllers 102, 104, 106, 108 may interface with one or more of the of the I/O controllers via a communication bus, such as an Ethernet or a controller area network (CAN) bus. However, other communications bus types may be used.

Each of the zone controllers 102, 104, 106, 108 is associated with a corresponding one of the zones 20, 22, 24, 26 in the first vehicle 10. In some embodiments, the zones 20, 22, 24, 26 may be defined to minimize lengths or costs of wiring between the zone controllers 102, 104, 106, 108 and the I/O controllers connected thereto.

As also shown in FIG. 4, the first vehicle 10 includes a first Ethernet network 110 interconnecting the zone controllers 102, 104, 106, 108. In some embodiments, and as shown in FIG. 4, the first vehicle 10 includes a plurality of RADAR sensors 122 each connected to a corresponding one of the zone controllers 102, 104, 106, 108 via a second Ethernet connection 124. The second Ethernet connections 124 may be separate from the first Ethernet network 110. Alternatively, the second Ethernet connections 124 may be integrated with the first Ethernet network 110. However, another type of communications network may be used to communicate RADAR sensor data from the RADAR sensors 122 to the zone controllers 102, 104, 106, 108.

In some embodiments, and as shown in FIG. 4, the first vehicle 10 includes a plurality of cameras 130 each connected to a corresponding one of the zone controllers 102, 104, 106, 108 via a serializer/deserializer (SerDes) connection 132. However, another type of communications network may be used to communicate image data from the cameras 130 to the zone controllers 102, 104, 106, 108.

The system of the present disclosure provides for a hardware architecture and a software architecture. In some embodiments, the hardware architecture is separate and isolated from the software architecture. The system of the present disclosure provides for hardware simplification by optimizing harnesses and using a single, common design for the zone controllers. The system of the present disclosure provides for software simplification by using a single software stack with the physical backbone as a “shared memory”. In some embodiments, one or more software applications may be executed on any of the zone controllers. In some embodiments, all software applications in the system may be executed on any of the zone controllers.

In some embodiments, a given one of the zone controllers 102, 104, 106, 108 may not be able to perform all functions of a single functional domain, such as infotainment, powertrain and vehicle dynamics, connectivity, body and comfort, and/or Advanced Driver Assistance Systems (ADAS), which may include driving automation. However, a combination of a plurality of zone controllers, such as four or more of the zone controllers, with Software hosted in a balanced configuration, and a ultra-high speed backbone (e.g. a network supporting speeds of 10 Gigabit per second (Gbps) or greater) can execute feature application software of all Domains. For example, each of the zone controllers may be able to process up to 3 or 4 camera feeds. This would not be adequate for ADAS features. But 4 of the zone controllers can process 12 to 16 cameras. Together they can execute ADAS features [at least] up to level 3 based on the “Levels of Driving Automation” standard by SAE International that defines six levels of driving automation, as specified in SAE standard J3016.

In some embodiments, the zone controllers 102, 104, 106, 108 may have identical hardware and configured to data via an ultra-fast backbone, as if it is shared memory, then together the zone controllers 102, 104, 106, 108 can be considered as a single Software execution environment 100, with pooled or combined hardware resources. For example, a system including four of the zone controllers 102, 104, 106, 108 may have four times the hardware resources of each of the zone controllers, 102, 104, 106, 108, alone. Hardware resources are distributed in the vehicle (by Zone Controller install locations) to minimize harness complexity.

In some embodiments, one or more of the zone controllers 102, 104, 106, 108 may process complex sensor data before exchanging it via the backbone to other ones of the of the zone controllers 102, 104, 106, 108. For example, a given one of the of the zone controllers 102, 104, 106, 108 that receives camera data should process this camera data first, and communicate a processed dataset for the camera image via the backbone to other ones of the of the zone controllers 102, 104, 106, 108. Processed data could be a compressed image, a cropped image, a subsampled image, or aby other form of data reduction. Alternatively, the given one of the of the zone controllers 102, 104, 106, 108 could determine objects in an image and communicate an object list via the backbone.

The use of identical hardware for each of a plurality of the zone controllers 102, 104, 106, 108 may provide benefits in manufacturing, lifecycle management, and may reduce cost by increased purchasing volumes (e.g., 4× same parts per vehicle) by providing for example a common configuration among the plurality of the zone controllers 102, 104, 106, 108. In one possible common configuration, the printed circuit board (PCB) may be common among the plurality of the zone controllers 102, 104, 106, 108. In another possible configuration the common configuration may include a common printed circuit board and some common populated hardware components such as common power components, and common communication components; with specialized configurations relating to the physical area of the vehicle associated with the zone controller may include a different microprocessor, and different input/output hardware components. In another possible configuration, the common configuration may include a common printed circuit board and some common populated hardware components such as common power components, and common communication components and common microprocessing components; with specialized configurations relating to the physical area of the vehicle associated with the zone controller including different input/output hardware components. Still in another possible configuration the common configuration may include all the hardware components and also optionally common software components; for example in the event the zone controllers control opposite physical areas of the vehicle having identical devices within the physical areas. In yet another possible configuration, the common configuration may also include common software among the plurality of zone controllers, and possibly specialized software associated with the physical area of the vehicle and the devices located therein. Other variations and sub-combinations of common configurations and specialized configurations are possible. In some embodiments, the system of the present disclosure may provide redundancy. For example, the system may be configured such that any of the zone controllers 102, 104, 106, 108 can host and execute any software in the first vehicle 10. This redundancy may also allow for load balancing. A resource manager can decide where to execute an application software based on available compute resources. Such a configuration may be called a software-defined vehicle (SDV) or a unified software environment (USE). In some embodiments, the resource manager may be distributed amongst one or more of the zone controllers 102, 104, 106, 108. Alternatively or additionally, the resource manager may be located in a separate controller that is independent of the zone controllers 102, 104, 106, 108.

### Optimization Process

Software functions are typically executed in the ECU where the critical sensor information is acquired. But in runtime, a vehicle-global scheduler may activate a software application function on any of the Zone controllers where adequate compute resource is available. The Ethernet Backbone will ensure that the function has access to the required inputs and parameters, and will be able to provide its outputs to the vehicle system.

In some embodiments, one or more of the zone controllers 102, 104, 106, 108 may include a microcontroller (MCU) safety domain. Time-critical functions may be executed in the MCU safety domain of the corresponding one of the zone controllers 102, 104, 106, 108. This MCU safety domain may be rated for Automotive Safety Integrity Level (ASIL) Functional Safety ASIL-D per functional safety standards, such as the risk classification scheme defined by the ISO 26262-Functional Safety for Road Vehicles standard.

In some embodiments, one or more of the zone controllers 102, 104, 106, 108 may include performance, or central, domain. High performance functions, such as machine learning, image processing, etc. may be executed in the central, or high performance domain of the corresponding one of the zone controllers 102, 104, 106, 108. This central, performance domain may be rated for a lower functional safety level than the MCU safety domain, such as ASIL-B. This central, performance domain may in one possible configuration be provided with a higher performance computing device and/or electronics and/or memory, as compared with a computing device associated with the zone controllers 102, 104, 106, 108.

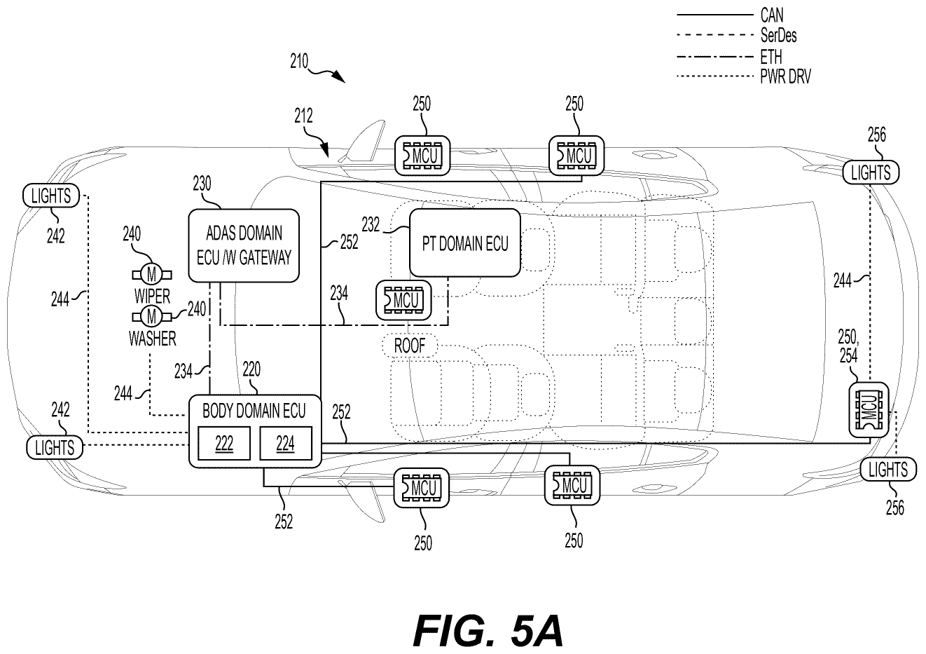

FIG. 5 shows a schematic diagram of a second vehicle 210 including a domain control system 212 with a modular ECU 220 having a power control board 222, and with remote power interfaces 250 located remotely from the modular ECU 220. In some embodiments, and as shown in FIG. 5, the modular ECU 220 may be used as a body ECU for controlling various devices and functions associated with the body of the vehicle. The body ECU may be distinguished from other ECUs in the vehicle, such as a powertrain control module (PCM) that is primarily used for controlling powertrain devices, such as engine actuators and sensors. The power control board 222 may also be called an amplifier board. The power control board 222 and the remote power interfaces 250 may each provide relatively high electrical current for operating various electrical loads, such as lights, motors, and other actuators. The modular ECU 220 also includes a compute board 224, which includes one or more high-performance processor devices configured to perform one or more application software functions. The application software functions may include, for example, processing signals from one or more sensors, and/or generating commands for operating one or more actuators. The application software functions may include complex computations, such as image processing, complex algorithms for motor current control, etc. The application software functions may include communications functions for communicating with other systems within the vehicle and/or for controlling input and output devices for communicating with a user.

The domain control system 212 includes an advanced driver-assistance system (ADAS) ECU 230 and a powertrain (PT) domain ECU 232 each in communication with the modular ECU 220 via Ethernet network interconnections 234. The Ethernet network interconnections 234 may provide high-speed and high-bandwidth communications between the ECUs 220, 230, 232 of the domain control system 212 within the second vehicle 210.

The second vehicle 210 also includes several motors 240 which may be used, for example, to actuate windshield wipers, and/or to pump washer fluid for cleaning the windshield of the second vehicle 210. The second vehicle 210 also includes front lights 242, which may include headlights, marker lights, turn signals, etc. The motors 240 and the front lights 242 are each connected to the modular ECU 220 via a power interconnection 244. Each of the power interconnections 244 may include that includes one or more cables and/or connectors. The modular ECU 220 supplies the electrical power to operate each of the motors 240 and the front lights 242 in the domain control system 212 of FIG. 5.

The domain control system 212 of FIG. 5 also includes several remote power interfaces 250, with each of the remote power interfaces 250 in communication with the modular ECU 220 via controller network interconnections 252. The controller network interconnections 252 may include Controller Area Network (CAN) and/or Local Interconnect Network (LIN) network interconnections, although other types of digital communications interfaces may be used.

The domain control system 212 of FIG. 5 also includes one of the remote power interfaces 250 that is configured as a rear light interface 254. The second vehicle 210 also includes two tail lights 256, which may include brake lights, turn signals, reverse indicating lights, etc. The tail lights 256 are each connected to the rear light interface 254 via a power interconnection 244, and the rear light interface 254 supplies the electrical power to operate each of the tail lights 256 in the domain control system 212 of FIG. 5.

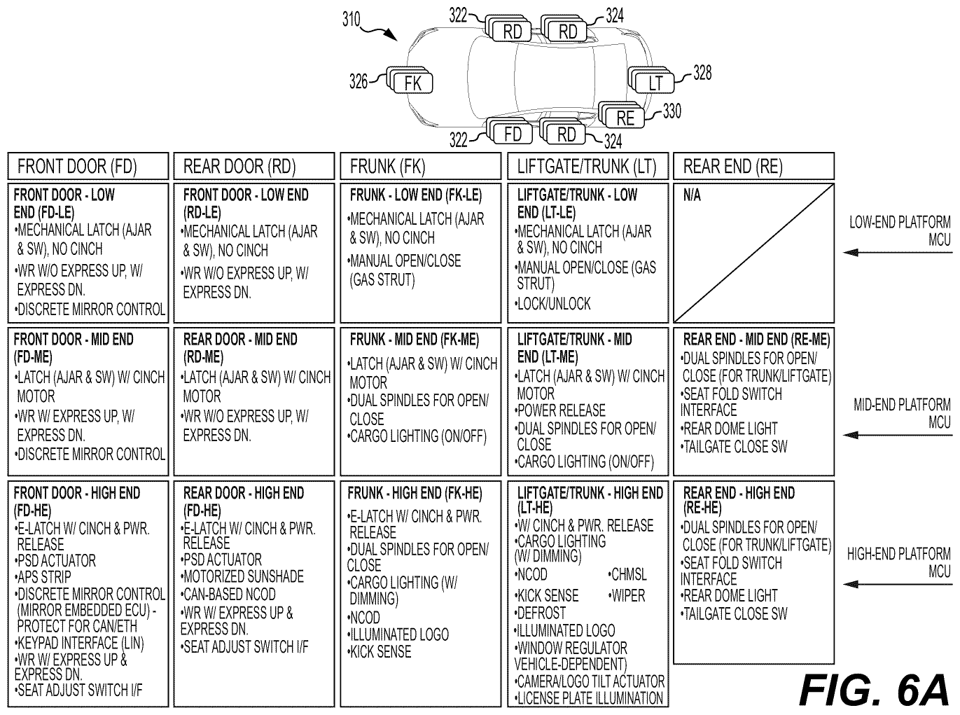

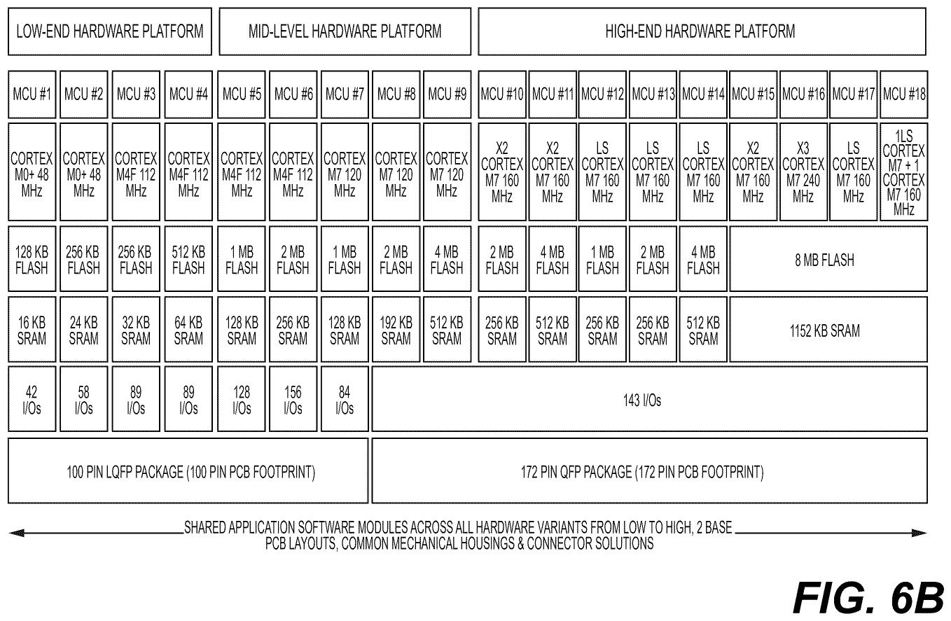

FIG. 6A shows a schematic diagram of a third vehicle 310 with a distributed electrical control system, in accordance with the present disclosure. The third vehicle 310 includes two front door (FD) I/O controllers 322, two rear door I/O controllers 324, a frunk (FK) I/O controller 326, a liftgate/trunk (LT) I/O controller 328, and a rear end (RE) I/O controller 330. As shown, the 5 different I/O controllers 322, 324, 326, 328, 330 have one of 3 different hardware platforms (low-end, mid-end, and high-end), and 14 different scalable variants (see FIG. 6B).

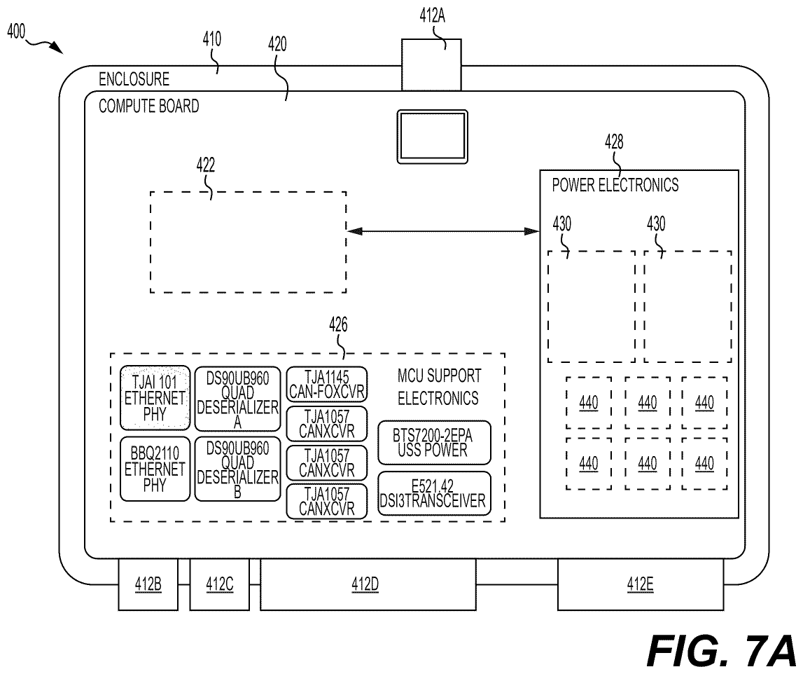

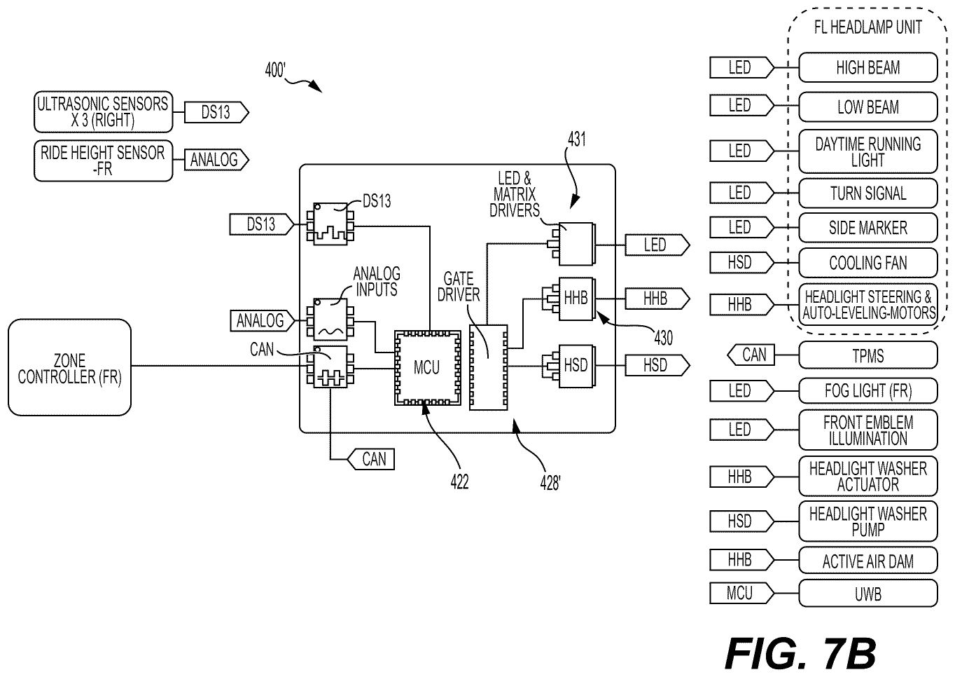

FIG. 7A shows an I/O controller 400 for a distributed electrical control system of a vehicle, in accordance with the present disclosure. The I/O controller 400 may be used to implement any or all of the I/O controllers 120 and/or any or all of the remote power interfaces 250. As shown, the I/O controller 400 includes an enclosure 410 containing a main circuit board 420 and defining a plurality of interfaces 412A, 412B, 412C, 412D, 412E, such as wiring connectors and/or receptacles for connecting power, communications, and signal wiring. Enclosure 410 is a separate, distinct, and remote enclosure than that of a central enclosure enclosing the modular ECU 220. Enclosure 410 may be mounted in closer proximity to the associated vehicle physical region governed by the I/O controller 400, for example such as within a closure panel or door cavity, or within a fender cavity, or compartment space such as a frunk or a trunk space, or other space of the associated physical vehicle region closer to the devices therein to be controlled.

The main circuit board 420 includes an ECU footprint 422 that is configured to physically and electrically receive one of a plurality of different processors each having different performance characteristics. The ECU footprint 422 may include, for example, a slot, socket, or an array of pads on a printed circuit board for connection to a pinout of a surface-mount integrated circuit (IC). The main circuit board 420 also includes a plurality of support electronics devices 426, such as power supply and conditioning hardware devices, network interface hardware devices, etc.

The I/O controller 400 also includes a power electronics section 428 having a plurality of I/O hardware devices. The power electronics section 428 may be arranged as part of the main circuit board 420. Additionally or alternatively, some or all of the power electronics section 428 may be provided as one or more separate boards, such as auxiliary printed circuit board (PCB) cards that are located in the enclosure 410 and connected electrically to the main circuit board 420. The power electronics section 428 includes two H-bridge footprints 430 that are unpopulated on the I/O controller 400 shown on FIG. 7A. The H-bridge footprints 430 may each include sockets, slots, or an arrangement of PCB features, such as pads and conductive traces for receiving an H-bridge device (not shown on FIG. 7A). The power electronics section 428 may include a different number of the H-bridge footprints 430. In a possible configuration, power electronics section 428 may be configured as a hybrid power section for both actuators and a light module. For example, power electronic section 428 may include one or more footprints for receiving a LED driver (see FIG. 7A). The power electronics section 428 also includes six FET footprints 440, that are unpopulated on the I/O controller 400 shown on FIG. 7A. The FET footprints 440 may each include sockets, slots, or an arrangement of PCB features, such as pads and conductive traces for receiving a solid-state switch, such as a field-effect transistor (FET) (not shown on FIG. 7A). The power electronics section 428 may include a different number of the FET footprints 440. FIG. 7A is an example of a commonized configuration of I/O controller 400, and illustratively a common configuration of the printed circuit board having footprints that can be populated, or left unpopulated depending on the specialization of the configuration for a particular zone of the vehicle, such as the number and types of devices located in the particular zone of the vehicle to be controlled by the respective I/O controller 400.

FIG. 7B shows an illustrative embodiment of an I/O controller 400′ for a front left zone-left front light/grille subzone for a distributed electrical control system of a vehicle having a hybrid power electronics section 428′.

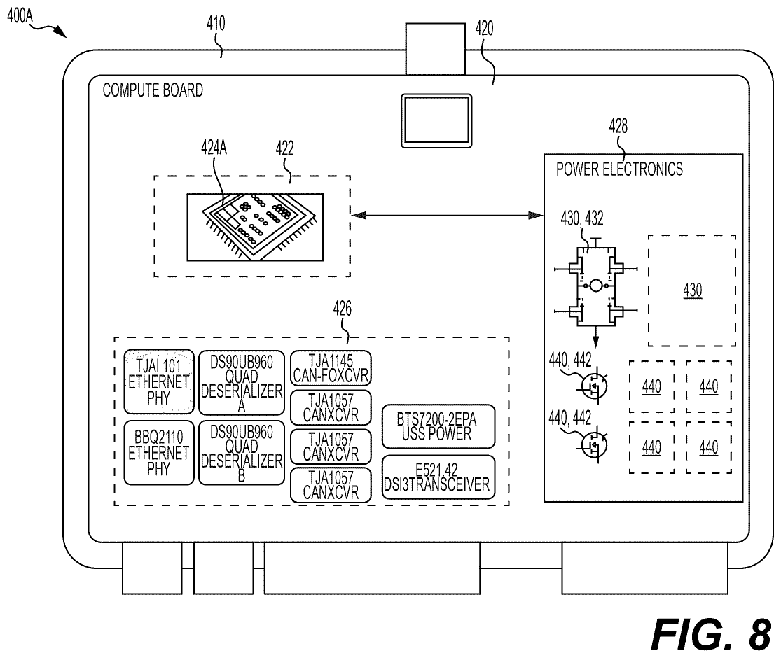

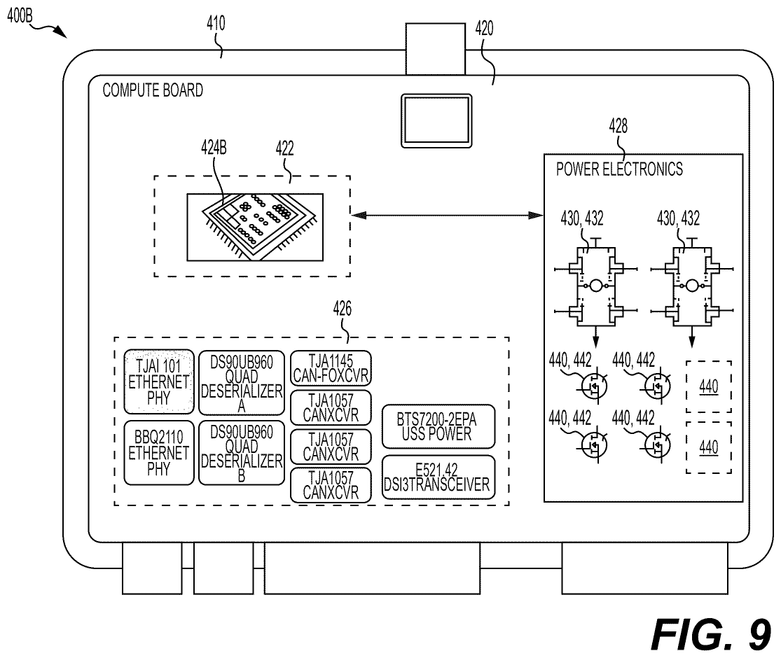

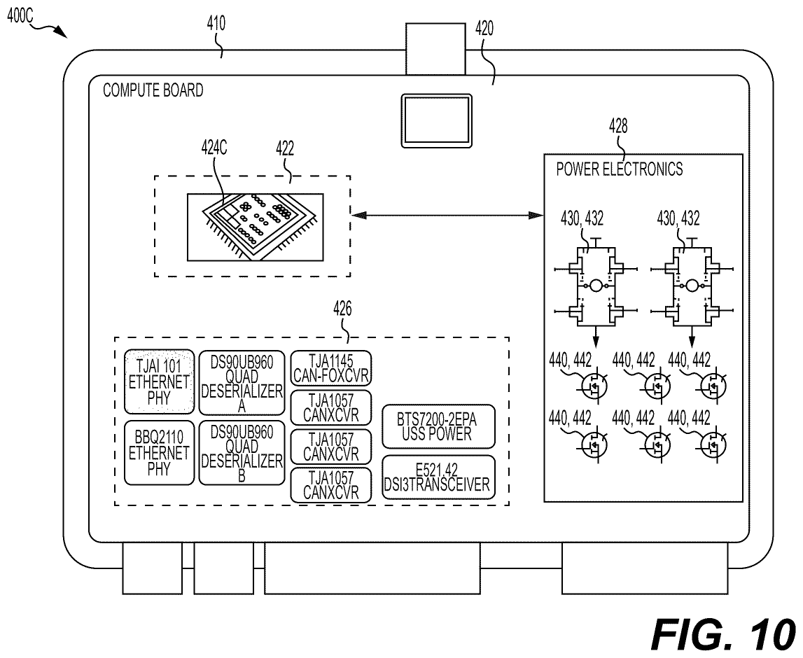

FIG. 8 shows a schematic diagram of a low-end configuration I/O controller 400A, FIG. 9 shows a schematic diagram of a mid-end configuration I/O controller 400B, and FIG. 10 shows a schematic diagram of a high-end configuration I/O controller 400C. Each of the I/O controllers 400A, 400B, 400C may be a variant of the I/O controller 400 shown on FIG. 7A, except with a corresponding processor 424A, 424B, 424C having different performance characteristics, and with a different arrangement of hardware components 432, 442 included in the respective power electronics sections 428. The low-end configuration I/O controller 400A shown in FIG. 8 includes one H-bridge device 432 connected to a corresponding one of the H-bridge footprints 430, and two solid-state switch devices 442 each connected to corresponding ones of the FET footprints 440. The mid-end configuration I/O controller 400B shown in FIG. 9 includes two H-bridge devices 432 each connected to a corresponding one of the H-bridge footprints 430, and four solid-state switch devices 442 each connected to corresponding ones of the FET footprints 440. The high-end configuration I/O controller 400C shown in FIG. 10 includes two H-bridge devices 432 each connected to a corresponding one of the H-bridge footprints 430, and six solid-state switch devices 442 each connected to corresponding ones of the FET footprints 440.

FIGS. 8 through 10 illustratively show different configurations of a zone controller having a common configuration, each illustratively shown as having a common printed circuit board and each having a specialized configuration illustratively shown as different types and/or number of hardware components populating the common printed circuit board. As one example of a specialized configuration, all the footprints of the printed circuit board are populated with hardware components shown in FIG. 10. As another example shown in FIGS. 8 and 9, less than all of the footprints of the printed circuit board are populated with hardware components.

The present disclosure provides an electrical control system for a vehicle. The electrical control system includes: a plurality of zone controllers each associated with a corresponding physical region of the vehicle, and each having an identical hardware configuration; a high-speed digital communications network interconnecting the plurality of zone controllers; and a plurality of I/O controllers. Each of the I/O controllers includes a processor and at least one of: an input circuit configured to receive a digital or analog signal from a sensor device, or an output circuit configured to produce and transmit a digital or analog signal to an output device. The plurality of I/O controllers each have a commonized configuration, including an identical enclosure and an identical main circuit board. Different I/O controllers of the plurality of I/O controllers have at least one of: processors having different performance characteristics, or at least one of the input circuit or the output circuit having different arrangements of hardware components.

In some embodiments, the different I/O controllers 400A, 400B, 400C have processors with different performance characteristics.

In some embodiments, the different I/O controllers have processors with different amounts of onboard memory.

In some embodiments, the at least one of the input circuit or the output circuit of the different I/O controllers have different arrangements of hardware components.

In some embodiments, the different I/O controllers each include a printed circuit board (PCB), and wherein at least one PCB of at least one of the different I/O controllers includes unpopulated space without corresponding ones of the hardware components that is omitted from a given arrangement of the hardware components in the at least one of the different I/O controllers.

In some embodiments, the at least one of the input circuit or the output circuit of the different I/O controllers includes output circuits having different numbers of hardware components associated with a given type of output channel.

In some embodiments, the hardware components associated with a particular one of the given type of output channel includes a solid-state switch.

In some embodiments, the hardware components associated with a particular one of the given type of output channel includes an H-bridge device.

The present disclosure also provides a domain control system for a vehicle. The domain control system includes: a modular electronic control unit; and a plurality of I/O controllers located remotely from the modular electronic control unit and in functional communication therewith via a controller network interconnection. The modular electronic control unit includes an enclosure and a compute board disposed within the enclosure and including one or more high-performance processor devices configured to perform one or more application software functions. The plurality of I/O controllers each include a processor and at least one of: an input circuit configured to receive a digital or analog signal from a sensor device, or an output circuit configured to produce and transmit a digital or analog signal to an output device. The plurality of I/O controllers each have a commonized configuration, including an identical enclosure and an identical main circuit board. Different I/O controllers of the plurality of I/O controllers have at least one of: processors having different performance characteristics, or at least one of the input circuit or the output circuit having different arrangements of hardware components.

In some embodiments, the different I/O controllers have processors with different performance characteristics.

In some embodiments, the different I/O controllers have processors with different amounts of onboard memory.

In some embodiments, the at least one of the input circuit or the output circuit of the different I/O controllers have different arrangements of hardware components.

In some embodiments, the different I/O controllers each include a printed circuit board (PCB), and wherein at least one PCB of at least one of the different I/O controllers includes unpopulated space without corresponding ones of the hardware components that is omitted from a given arrangement of the hardware components in the at least one of the different I/O controllers.

In some embodiments, the at least one of the input circuit or the output circuit of the different I/O controllers includes output circuits having different numbers of hardware components associated with a given type of output channel.

In some embodiments, the hardware components associated with a particular one of the given type of output channel includes at least one of: a solid-state switch, or an H-bridge device.

The present disclosure also provides an I/O controller for a control system in a vehicle. The I/O controller includes: a main circuit board; an enclosure containing the main circuit board; and at least one of: an input circuit configured to receive a digital or analog signal from a sensor device, or an output circuit configured to produce and transmit a digital or analog signal to an output device. The main circuit board is configured to physically and electrically receive one of a plurality of different processors each having different performance characteristics. The I/O controller is configured for functional communication with a remote electronic control unit via a controller network interconnection.

In some embodiments, the plurality of different processors have at least one of: different amounts of onboard memory, different clock speeds, or different numbers of I/O channels.

The present disclosure also provides an I/O controller for a control system in a vehicle. The I/O controller includes a main circuit board, and an enclosure containing the main circuit board. The main circuit board includes a plurality of footprints each configured to receive one or more hardware components to define one of: an input circuit configured to receive a digital or analog signal from a sensor device, or an output circuit configured to produce and transmit a digital or analog signal to an output device. Footprints, also referred to as a PCB footprint is illustratively the interface between the PCB and the hardware component, providing signal connection physical between the hardware component and the PCB. For example, it may be the layout on a printed circuit board (PCB), or a landing pattern, for providing a proper alignment with the interface components of a hardware component and where the hardware component may be soldered to form an electrical connection, and may include pads or apertures for receiving pins of the hardware component. In addition to soldering, other manners of establishing a connection may include without limitation press fit and locking type connections. The I/O controller is operable with at least one of the footprints populated with hardware components, and wherein the at least one of the footprints populated with hardware components is fewer than all of the footprints, thereby providing the I/O controller with a given number of I/O channels that is fewer than a number of I/O channels corresponding to all of the footprints being populated. The I/O controller is configured for functional communication with a remote electronic control unit via a controller network interconnection.

In some embodiments, the one or more hardware components populated on the at least one of the footprints includes a solid-state switch.

In some embodiments, the one or more hardware components populated on the at least one of the footprints includes an H-bridge device

The present disclosure provides an electrical control system for a vehicle with I/O controllers 400, which may also be called edge controllers or amplifier boards, and which have quasi-communized construction. The present disclosure provides I/O controllers 400 having a commonized platform, with scalable processors types. In other words, the supporting components of the processors may be commonized, and not the processor itself. The processor is selected to have the same footprint e.g. pin layout for all the levels of performance types i.e. low, medium, high performance.

For example, I/O controllers 400 may each have identical PCB layouts, the components supporting the processor inputs/outputs/communications/power supply are commonized. And the footprint on the PCB for receiving the different chips (high performance/medium performance/lower performance) is the same on all the PCB layouts of the amplifier boards. Cost reduction is achieved by volume production without customization for each processor type. Also, the footprints 430, 440 for all the power electronics may be the same on each board, but populated with the components needed for the zone of the vehicle being controlled. Cost reduction is achieved by volume production by populating the power electronics required.

The I/O controllers 400 of the present disclosure provide for optimization of processor type for the type of components to be controlled in a particular zone or application. In other words, the I/O controllers 400 of the present disclosure provide flexibility to reduce waste in alternative solutions that may require excessive processor power and extra power electronics to the handle the greatest functional requirement, and which may not be needed in light of the devices located in a particular zone it is controlling.

For example for complex controlled systems, like a front door which has an electronic latch (e-latch), a haptic/servo controlled power side door actuator, a side mirror, obstacle detection sensors and cameras which may be controlled and monitored, you can select the high end ECU and basically drop it into the PCB without any other changes to the board. In a similar manner, for a rear end zone, you can drop in a lower-performance ECU into the PCB board without making any changes to the board since possibly only a simple power release liftgate latch and a break light needs to be powered/controlled.

Also, the I/O controllers 400 of the present disclosure provide further optimization by using a common-design PCB with a maximum number footprints for the FETS and H-bridges for the vehicle and only populate those spots as needed for the particular vehicle zone. For example in a front zone, the I/O controller 400 may need to control a powered frunk hinge needing 1 H-bridge and 1 FET for bi-directional hinge motor control, and 1 FET for the frunk latch (single directional release as the pawl would have a reset spring not needing a reverse motor control). Then for example, in a side door zone, another I/O controller 400 may need to control a side door mirror unfolding motor hinge needing 1 H-bridge and 1 FET, a power side door actuator needing another dedicated H-bridge and FET for bi-directional motor control, 1 FET for the side door latch release (single directional release as the pawl would have a reset spring), and 1 FET for a cinch motor control (cinch motor having a spring reset), and 1 FET for illuminating a door handle. So, the processing power based on the needs of a specific zone are scalable using a common PCB board, and the power components are scalable using a common PCB for the type of actuators to be controlled in a particular zone.

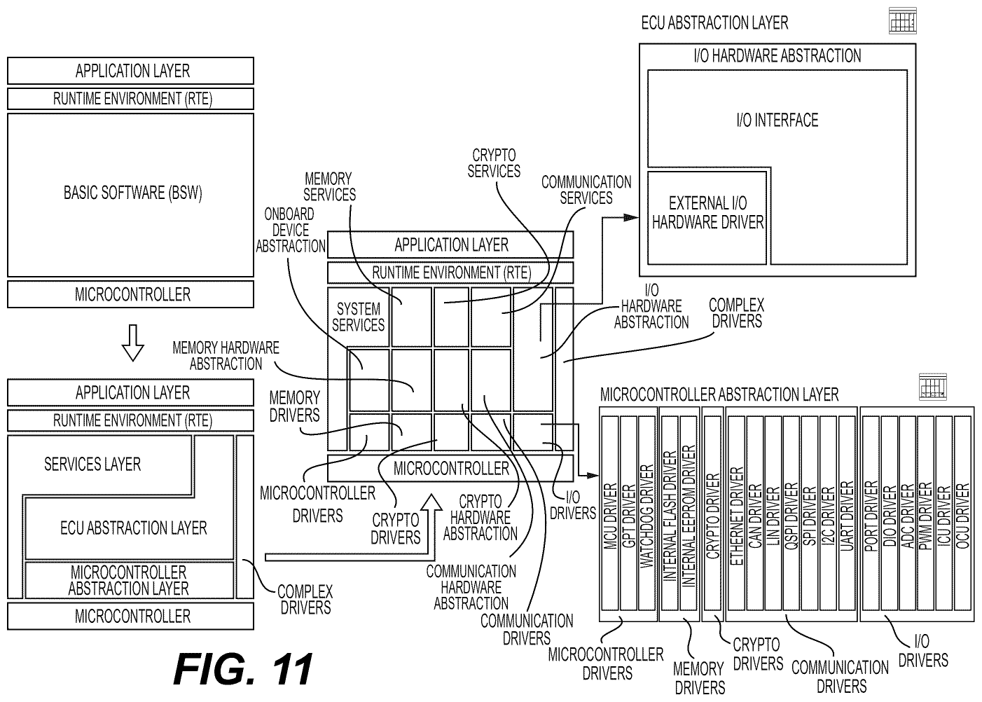

Now referring to FIG. 11, the herein described hardware variations may share common software throughout all variants. This software would follow a standard such as the automotive open system architecture (AUTOSAR) framework so that code would be portable across devices within the product family. FIG. 11 illustrates reusable software modules portable across different microcontrollers and hardware platforms. Such a configuration provides for abstracting the software from physical device control—i.e. a PWM drive function could be used for a lamp, liftgate, or any motor or solenoid as an example, irrespective of its domain or location within the vehicle. As a result, same module may be referenced in software to set up PWM for both a lamp or liftgate, however the low-level drivers could handle all of the device-specific complexity. Both off the bookshelf software and hardware components may be utilized for integration of hardware and software blocks that satisfy a particular application requirement.

The system, methods and/or processes described above, and steps thereof, may be realized in hardware, software or any combination of hardware and software suitable for a particular application. The hardware may include a general purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or alternatively, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices as well as heterogeneous combinations of processors processor architectures, or combinations of different hardware and software, or any other machine capable of executing program instructions.

Thus, in one aspect, each method described above and combinations thereof may be embodied in computer executable code that, when executing on one or more computing devices performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

The foregoing description is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An electrical control system for a vehicle, comprising:
a plurality of zone controllers each associated with a corresponding physical region of the vehicle, wherein each zone controller is configured to control at least one device located within the corresponding physical region of the vehicle;
wherein each zone controller comprises a configuration that is common among the plurality of zone controllers and a configuration that is specialized for controlling the at least one device of the corresponding physical region of the vehicle.

2. The electrical control system of claim 1, wherein the configuration that is common among the plurality of zone controllers comprises a common printed circuit board (PCB).

3. The electrical control system of claim 2, wherein the common printed circuit board comprises an identical number of footprints each configured to receive a hardware component.

4. The electrical control system of claim 3, wherein the configuration that is specialized for controlling the at least one device of the corresponding physical region of the vehicle comprises a set of hardware components populating less than all of the identical footprints of the common circuit board.

5. The electrical control system of claim 3, wherein the configuration that is specialized for controlling the at least one device of the corresponding physical region of the vehicle comprises a set of hardware components populating the identical footprints of one common circuit board that is different from another set of hardware components populating the identical footprints of another common circuit board.

6. The electrical control system of claim 3, wherein one of the identical number of footprints includes a footprint for receiving a microcontroller.

7. The electrical control system of claim 6, wherein the footprint for receiving the microcontroller is identical on each common printed circuit board.

8. The electrical control system of claim 6, wherein the footprint for receiving the microcontroller is adapted to receive the microcontroller having a processor with different performance characteristic.

9. The electrical control system of claim 1, wherein the common configuration is an identical hardware configuration.

10. The electrical controller system of claim 9, wherein each identical hardware configuration comprises:
a high-speed digital communications network interconnecting the plurality of zone controllers; and
a plurality of I/O controllers each including a processor and at least one of: an input circuit configured to receive a digital or analog signal from a sensor device, or an output circuit configured to produce and transmit a digital or analog signal to an output device,
wherein the plurality of I/O controllers each have a commonized configuration including an identical enclosure and an identical main circuit board, and
wherein different I/O controllers of the plurality of I/O controllers have at least one of:
the processors having different performance characteristics, or
the at least one of the input circuit or the output circuit having different arrangements of hardware components.

11. The electrical control system of claim 10, wherein the different I/O controllers have processors with different performance characteristics.

12. The electrical control system of claim 10, wherein the at least one of the input circuit or the output circuit of the different I/O controllers have different arrangements of hardware components.

13. The electrical control system of claim 12, wherein the different I/O controllers each include a printed circuit board (PCB), and wherein at least one PCB of at least one of the different I/O controllers includes unpopulated space without corresponding ones of the hardware components that is omitted from a given arrangement of the hardware components in the at least one of the different I/O controllers.

14. The electrical control system of claim 12, wherein the at least one of the input circuit or the output circuit of the different I/O controllers includes output circuits having different numbers of hardware components associated with a given type of output channel.

15. The electrical control system of claim 14, wherein the hardware components associated with a particular one of the given type of output channel includes at least one of: a solid-state switch, an H-bridge or half H-Bridge device, an LED driver, and/or an audio driver.

16. An I/O controller for a control system in a vehicle, comprising:
a main circuit board;
an enclosure containing the main circuit board; and
at least one of: an input circuit configured to receive a digital or analog signal from a sensor device, or an output circuit configured to produce and transmit a digital or analog signal to an output device,
wherein the main circuit board is configured to physically and electrically receive one of a plurality of different processors each having different performance characteristics, and
wherein the I/O controller is configured for functional communication with a remote electronic control unit via a controller network interconnection.

17. The I/O controller of claim 16, wherein the main circuit board has a processor footprint for electrical connection with a pinout of each of the plurality of different processors, wherein each layout of the pinout of each of the plurality of the different processors are identical and wherein the plurality of different processor have at least one of: different amounts of onboard memory, different clock speeds, or different numbers of I/O channels.

18. An I/O controller for a control system in a vehicle, comprising:
a main circuit board; and
an enclosure containing the main circuit board,
wherein the main circuit board includes a plurality of footprints each configured to receive one or more hardware components to define one of: an input circuit configured to receive a digital or analog signal from a sensor device, or an output circuit configured to produce and transmit a digital or analog signal to an output device,
wherein the I/O controller is operable with at least one of the footprints populated with hardware components, and wherein the at least one of the footprints populated with hardware components is fewer than all of the footprints, thereby providing the I/O controller with a given number of I/O channels that is fewer than a number of I/O channels corresponding to all of the footprints being populated, and
wherein the I/O controller is configured for functional communication with a remote electronic control unit via a controller network interconnection.

19. The I/O controller of claim 18, wherein the one or more hardware components populated on the at least one of the footprints includes at least one of a solid-state switch, an H-bridge, and an LED driver.

20. The I/O controller of claim 19, wherein the output devices associated with the one or more hardware components includes at least one of a power actuator and a lighting device.
